(19) United States
(12) Patent Application Publication
(10) Pub. No.: US 2014/0139998 A1
(43) Pub. Date: May 22, 2014

(54) SERVER RACK

(71) Applicants: INVENTEC (PUDONG) TECHNOLOGY CORPORATION, Shanghai (CN); INVENTEC CORPORATION, Taipei City (TW)

(72) Inventors: Hui-Ming TASI, Taipei City (TW); Chih-Lung LIAO, Taipei City (TW)

(73) Assignees: INVENTEC CORPORATION, Taipei City (TW); Inventec (Pudong) Technology Corporation, Shanghai (CN)

(21) Appl. No.: 13/846,264

(22) Filed: Mar. 18, 2013

(30) Foreign Application Priority Data
Nov. 20, 2012 (CN) 201210472259.7

(51) Int. Cl. H05K 7/18; G06F 1/20

(52) U.S. Cl. CPC H05K 7/18; G06F 1/20
USPC 361/679.48; 211/26

(57) ABSTRACT

A server rack includes a main frame and a fan bracket. The main frame has at least one first pivoting member and at least one first fixing member. The fan bracket has at least one second pivoting member and at least one second fixing member respectively corresponding to the first pivoting member and the first fixing member. The second pivoting member of the fan bracket is detachably connected to the first pivoting member, so that the fan bracket is capable of pivoting relative to the main frame from an open position to a closed position. Thereby, the second fixing member is detachably connected to the first fixing member.

### CROSS-REFERENCE TO RELATED APPLICATIONS

This non-provisional application claims priority under 35 U.S.C. §119(a) on Patent Application No(s). 201210472259.7 filed in China, P.R.C. on Nov. 20, 2012, the entire contents of which are hereby incorporated by reference.

### BACKGROUND OF THE INVENTION

1. Technical Field of the Invention

The disclosure relates to a rack, and more particularly to a server rack having a fan bracket.

2. Description of the Related Art

In recent years, computer servers gradually develop from a conventional bulky tower server to a rack server that centrally manages 1 U (U refers in particular to the thickness of the rack server in the server field, and 1 U=4.445 cm) server hosts in a cabinet.

Generally speaking, the server hosts in the rack server are slideably disposed in the cabinet. Specifically, a chassis for server units configured for being placed horizontally may be mounted in the cabinet. Moreover, the server units are connected to one another, so as to expand functions of the server. Thereby a high operational performance is achieved.

In addition, for enhancing the heat dissipation effect, the cabinet may further comprise a main frame and a fan bracket. The fan bracket is equipped with a plurality of fan apparatuses for dissipating heat from a plurality of electronic devices in the cabinet. The fan bracket is generally fixed to the main frame by screw fastening. Specifically, mounting of the fan bracket requires two technicians to work at the same time. That is, one of the technicians holds the fan bracket to temporarily fix the fan bracket to the main frame, and the other technician, meanwhile, fastens screws to the fan bracket and the main frame. Thereby, the assembly of the fan bracket to the main frame is completed.

Since the assembly of the fan bracket to the main frame requires cooperation of two technicians, and a room for accommodating the rack server usually has limited space, it is inconvenient for the two technicians to assemble the fan bracket to the main frame in the small space. Thus, the efficiency in assembling fan bracket and the main frame is unsatisfactory.

### SUMMARY OF THE INVENTION

In an embodiment, the disclosure provides a server rack comprising a main frame and a fan bracket. The main frame has at least one first pivoting member and at least one first fixing member. The fan bracket has at least one second pivoting member and at least one second fixing member respectively corresponding to the first pivoting member and the first fixing member. The second pivoting member of the fan bracket is detachably connected to the first pivoting member, so that the fan bracket is configured for pivoting relative to the main frame from an open position to a closed position. Thereby, the second fixing member is detachably connected to the first fixing member.

### BRIEF DESCRIPTION OF THE DRAWINGS

The disclosure will become more fully understood from the detailed description given herein below for illustration only, and thus does not limit the disclosure, wherein:

FIG. 1 is an exploded view of a server rack according to an embodiment of the disclosure;

FIG. 2 is a schematic assembled view of second pivoting members of a fan bracket and first pivoting members of a main frame according to an embodiment of the disclosure;

FIG. 3 is a partial enlarged view of a server rack in FIG. 2;

FIG. 4 is a schematic assembled view of second fixing members of a fan bracket and first fixing members of a main frame according to an embodiment of the disclosure; and

FIG. 5 is a partial enlarged view of a server rack in FIG. 4.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

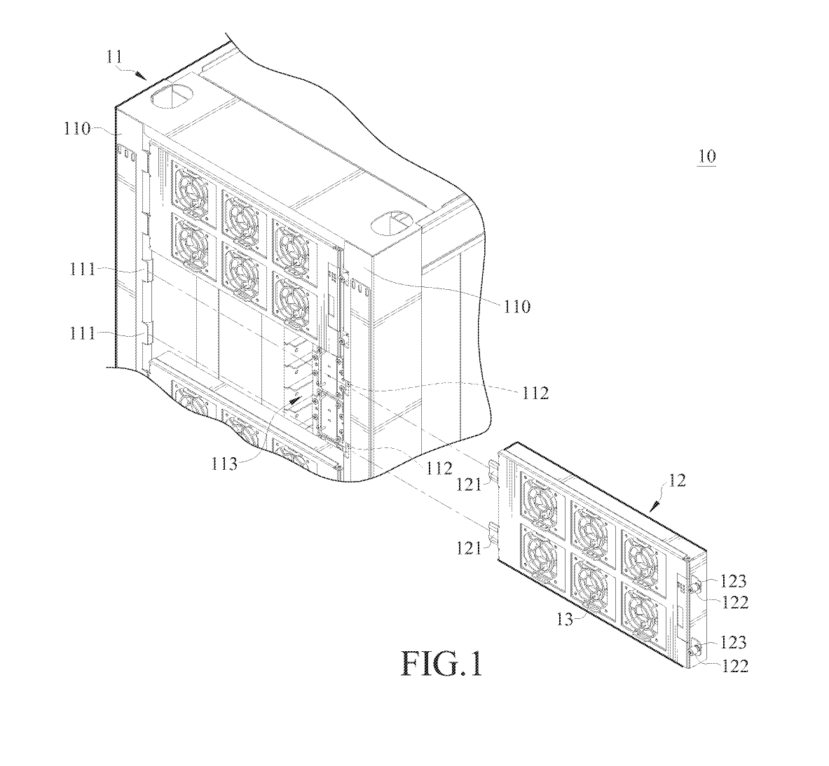

Referring to FIG. 1, FIG. 1 is an exploded view of a server rack according to an embodiment of the disclosure.

A server rack 10 of this embodiment comprises a main frame 11, a plurality of fan brackets 12, and a plurality of fans 13 disposed on each of the fan brackets 12. In this embodiment, the number of the fan brackets 12 comprised in the server rack 10 is not intended to limit the disclosure. In some other embodiments, the server rack 10 comprises one fan bracket 12.

The main frame 11 comprises two opposite side columns 110 and an accommodation space 113 between the two side columns 110. Each of the two side columns 110 has at least one first pivoting member 111 and at least one first fixing member 112. That is, the first pivoting member 111 and the first fixing member 112 are located on two opposite sides of the accommodation space 113. Specifically, the first pivoting member 111 of this embodiment is a slot, and the first fixing member 112 is a fastening hole, such as a screw hole. In addition, the main frame 11 of this embodiment has a plurality of first pivoting members 111 and a plurality of first fixing members 112, and every two of the first pivoting members 111 and every two of the first fixing members 112 correspond to one of the fan brackets 12. However, the numbers of the first pivoting members 111 and the first fixing members 112 corresponding to one of the fan brackets 12 are not intended to limit the disclosure, but can be adjusted by persons skilled in the art when needed.

On each of two opposite sides of the fan bracket 12, two second pivoting members 121 corresponding to two of the first pivoting members 111 and two second fixing members 122 corresponding to two of the first fixing members 112 are provided. Specifically, each of the second pivoting members 121 of this embodiment is a tongue structure protruding from one side edge of the fan bracket 12. In addition, two ear portions 123 protrude from one side of the fan bracket 12 opposite to the second pivoting members 121 (tongue structures), and the two second fixing members 122 are inserted through the two ear portions 123 respectively. In this and some other embodiments, the second fixing member 122 is a fastener, such as a thumbscrew. Nevertheless, the numbers of the second pivoting member 121 and the second fixing member 122 are not intended to limit the disclosure, but can be adjusted by persons skilled in the art as required.

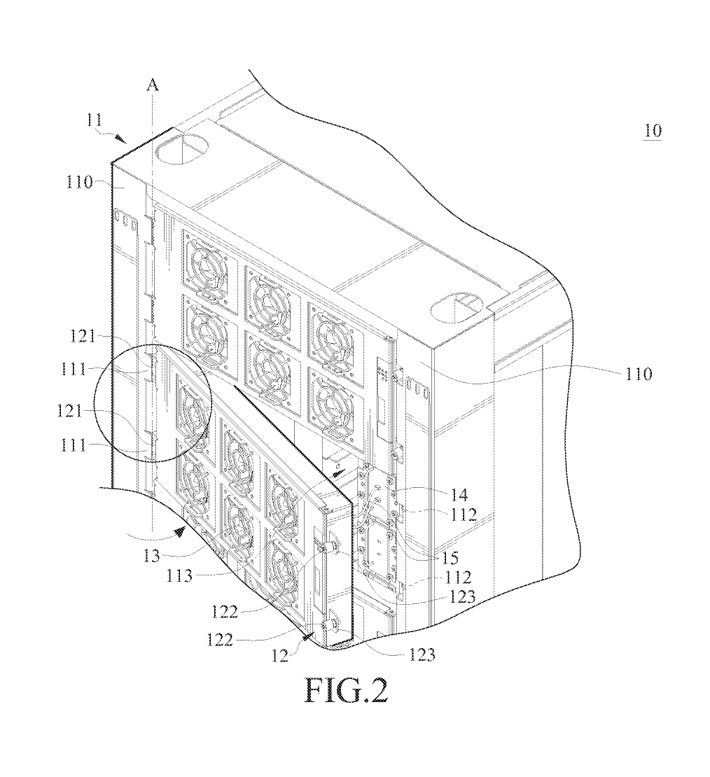

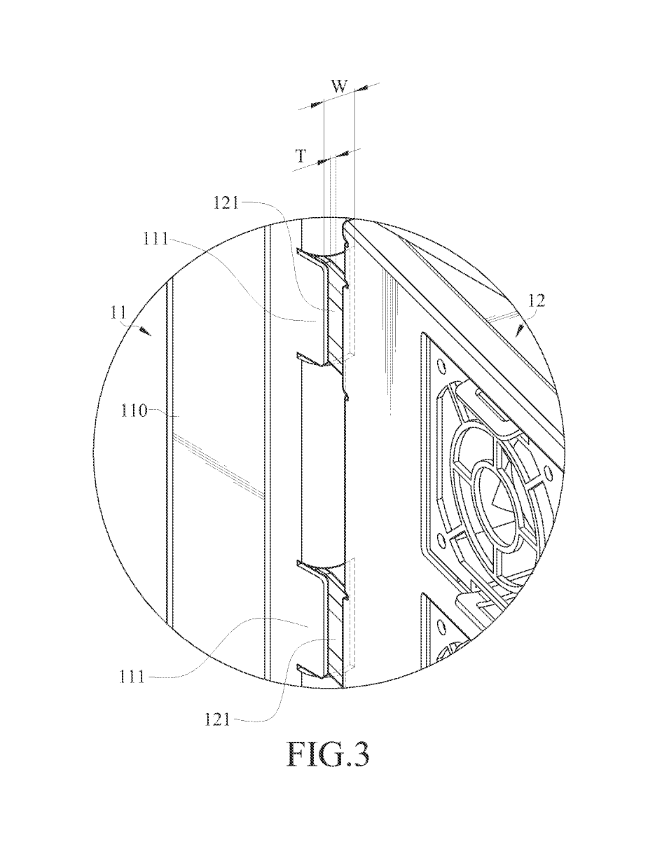

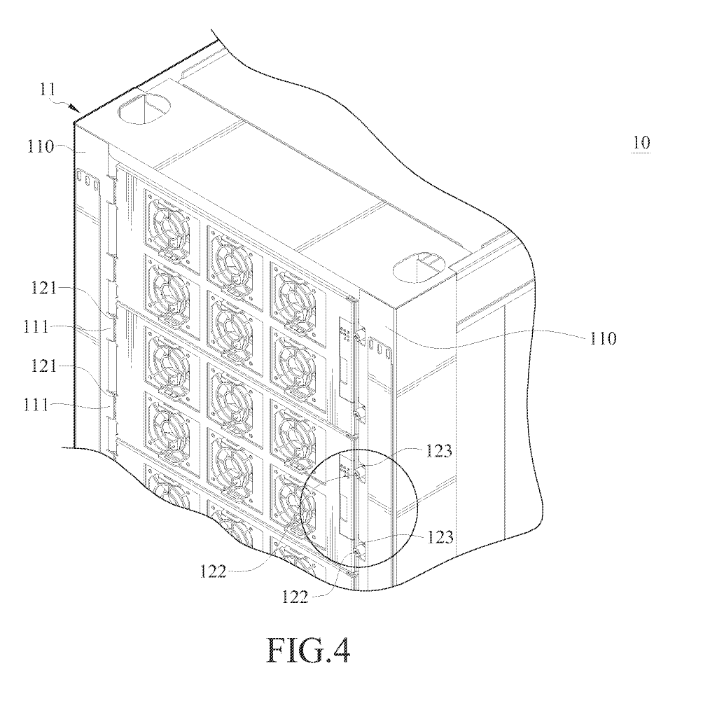

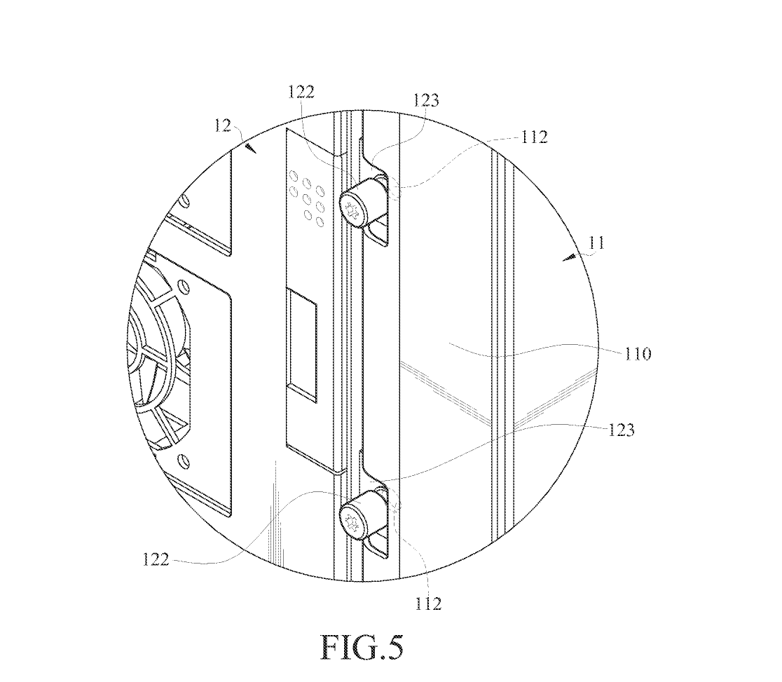

Please refer to FIG. 2 to FIG. 5. FIG. 2 is a schematic assembled view of second pivoting members of a fan bracket and first pivoting members of a main frame according to an embodiment of the disclosure. FIG. 3 is a partial enlarged view of a server rack in FIG. 2. FIG. 4 is a schematic assembled view of second fixing members of a fan bracket and first fixing members of a main frame according to an embodiment of the disclosure. FIG. 5 is a partial enlarged view of a server rack in FIG. 4.

When a technician intends to assemble the fan bracket 12 to the main frame 11, the technician only needs to obliquely insert the second pivoting members 121 (tongue structures) into the first pivoting members 111 (slots), so as to position one side of the fan bracket 12 the main frame 11. Hence, the fan bracket 12 is maintained exposed out of the accommodation space 113, namely at an open position (as shown in FIG. 2). At this time, the second fixing members 122 (thumbscrews) of the fan bracket 12 are located at a distance from and not in contact with the first fixing members 112 (fastening holes) of the main frame 11.

Then, the technician electrically connects one end of a signal line 15 to the fans 13 on the fan bracket 12, and electrically connects the other end of the signal line 15 to a circuit board 14 in the main frame 11, as shown in FIG. 2.

As shown in FIG. 3, the slot width W of the first pivoting member 111 (slot) is greater than the thickness T of the second pivoting member 121 (tongue structure). Therefore, when the second pivoting members 121 (tongue structures) are inserted into the first pivoting members 111 (slots), a sufficient space is provided for movement of the second pivoting members 121 (tongue structures) within the first pivoting members 111 (slots). Thus, the fan bracket 12 is configured for pivoting around an arrangement direction A of the first pivoting members 111 (slots) relative to the main frame 11 from the open position (as shown in FIG. 2) to a closed position (as shown in FIG. 4).

At this time, the fan bracket 12 is located between the two side columns 110 and inside the accommodation space 113, and the second fixing members 122 (thumbscrews) of the fan bracket 12 are close to and in contact with the first fixing members 112 (fastening holes) of the main frame 11. Accordingly, the technician rotates the second fixing members 122 (thumbscrews) to fasten the second fixing members 122 (thumbscrews) into the first fixing members 112 (fastening holes), thus completing the assembly of the fan bracket 12 to the main frame 11.

According to the above, the process of positioning the fan bracket 12 to the main frame 11 followed by wiring and fixing the fan bracket 12 to the main frame 11 may be simply completed by one technician.

In this embodiment, the first pivoting member 111 of is exemplified using the slot, and the second pivoting member 121 is exemplified using the tongue structure, but the disclosure is not limited thereto. In some other embodiments, the first pivoting member 111 is changed from the slot to the tongue structure, and the second pivoting member 121 is changed from the tongue structure to the slot.

In addition, the first fixing member 112 of this embodiment is exemplified using the fastening hole, and the second fixing member 122 is exemplified using the thumbscrew, but the disclosure is not limited thereto. In some other embodiments, the first fixing member 112 is a socket or a hook, and the second pivoting member 121 is a pin for mating with the socket or a recess for mating with the hook.

According to the server rack disclosed in the above embodiments, since the second pivoting member of the fan bracket is detachably connected to the first pivoting member of the main frame, the fan bracket is preliminarily positioned to the main frame. Furthermore, as the fan bracket pivots relative to the main frame from the open position to the closed position, the second fixing member is connected with the first fixing member, thus completing assembly of the fan bracket to the main frame. Therefore, the server rack of the disclosure can be easily assembled or disassembled by one person. Thereby the assembly efficiency is improved.

What is claimed is:

1. A server rack, comprising:
a main frame having at least one first pivoting member and at least one first fixing member; and
a fan bracket having at least one second pivoting member and at least one second fixing member respectively corresponding to the first pivoting member and the first fixing member, the second pivoting member of the fan bracket being detachably connected to the first pivoting member, so that the fan bracket is configured for pivoting relative to the main frame from an open position to a closed position, in order that the second fixing member is detachably connected to the first fixing member.

2. The server rack according to claim 1, wherein the first pivoting member is a slot, and the second pivoting member is a tongue structure.

3. The server rack according to claim 1, wherein the first fixing member is a fastening hole, and the second fixing member is a fastener.

4. The server rack according to claim 3, wherein the fastening hole is a screw hole, and the fastener is a thumbscrew inserted through the fan bracket.

5. The server rack according to claim 1, further comprising a plurality of fans, the plurality of fans being located on the fan bracket.

6. The server rack according to claim 5, further comprising a circuit board and a signal line, the circuit board being located in the main frame, and the signal line being electrically connected to the fans and the circuit board.

7. The server rack according to claim 1, wherein the main frame has an accommodation space, and the first pivoting member and the first fixing member are located on two opposite sides of the accommodation space.

8. The server rack according to claim 1, wherein the second pivoting member and the second fixing member are located on two opposite sides of the fan bracket.
